(19) United States
(12) Patent Application Publication
(10) Pub. No.: US 2026/0013324 A1
(43) Pub. Date: Jan. 8, 2026

(54) LIGHT EMITTING ELEMENT, AND DISPLAY DEVICE AND ELECTRONIC DEVICE INCLUDING THE SAME

(71) Applicant: Samsung Display Co., LTD., Yongin-si (KR)

(72) Inventors: Hyun Eok SHIN, Yongin-si (KR); Joon Yong PARK, Yongin-si (KR); Ju Hyun LEE, Yongin-si (KR); Sam Tae JEONG, Yongin-si (KR); Yung Bin CHUNG, Yongin-si (KR)

(21) Appl. No.: 19/098,223

(22) Filed: Apr. 2, 2025

(30) Foreign Application Priority Data
Jul. 5, 2024 (KR) 10-2024-0088833

(51) Int. Cl. H10K 50/816; H10K 50/818; H10K 102/00; H10K 102/10

(52) U.S. Cl. CPC H10K 50/816; H10K 50/818; H10K 2102/103; H10K 2102/351

(57) ABSTRACT

A light emitting element includes an anode electrode and a cathode electrode opposing each other; and a light emitting layer disposed between the anode electrode and the cathode electrode. The anode electrodes include a reflective layer including a reflective metal material; a blocking layer disposed on one surface of the reflective layer; and a skin layer disposed on the blocking layer.

This application claims priority to Korean Patent Application No. 10-2024-0088833 filed on Jul. 5, 2024, and all the benefits accruing therefrom under 35 U.S.C. 119, the contents of which in its entirety is herein incorporated by reference.

### BACKGROUND

### 1. Technical Field

The present disclosure relates to a light emitting element, and a display device and an electronic device including the same.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

The display device may be a flat panel display device such as a liquid crystal display device, a field emission display device, or a light emitting display device. Here, the light emitting display device may include an organic light emitting display device including an organic light emitting element, an inorganic light emitting display device including an inorganic light emitting element such as an inorganic semiconductor, and a micro or nano light emitting display device including a micro or nano light emitting element.

The organic light emitting display device displays an image using light emitting elements each including a light emitting layer made of an organic light emitting material. As such, as the organic light emitting display device implements image display using self-light emitting elements, the organic light emitting display device may have relatively superior performance in terms of power consumption, response speed, emission efficiency, luminance, and wide viewing angle compared to other display devices.

One surface of the display device may be a display surface including a display area where an image is displayed. Light emitting areas that emit light with respective luminance and color may be arranged in the display area.

### SUMMARY

The light emitting elements of the display device include an anode electrode and a cathode electrode opposing each other.

Considering a light emission efficiency of the light emitting element, one of the anode electrode and the cathode electrode may transmit light and the other may reflect light.

That is, the anode electrode of the light emitting element may include a reflective layer that reflects light.

The reflective layer includes a metal material having reflective properties.

However, since the metal material having reflective properties has a relatively large deformation rate due to heat, the metal material of the reflective layer may stretch or expand, or may diffuse to the surroundings and be lost, during a heat treatment process after the anode electrode is disposed. As a result, the display quality and lifespan of the display device may be reduced due to a decrease in the luminance of the light emitting element or damage to the light emitting element.

Aspects of the present disclosure provide a light emitting element capable of reducing deformation of a reflective layer, and a display device and an electronic device including the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a light emitting element includes an anode electrode and a cathode electrode opposing each other; and a light emitting layer disposed between the anode electrode and the cathode electrode. The anode electrodes include a reflective layer including a reflective metal material; a blocking layer disposed on a top surface of the reflective layer; and a skin layer disposed on the blocking layer.

The blocking layer may include amorphous indium tin oxide (ITO) containing silicon dioxide (SiO₂). The skin layer may include crystalline indium tin oxide (ITO).

The content of silicon dioxide in the amorphous indium tin oxide may be in the range of about 1.0 weight percent (wt %) to about 10.0 wt % with respect to a total weight of the amorphous indium tin oxide.

The reflective layer may include silver (Ag) or a silver alloy.

A thickness of each of the blocking layer and the skin layer may be in the range of about 5 nanometers (nm) to about 10 nm. A thickness of the reflective layer may be in the range of about 80 nm to about 100 nm.

The anode electrode may further include an additional blocking layer disposed on a bottom surface of the reflective layer. The reflective layer may be interposed between the blocking layer and the additional blocking layer. The additional blocking layer may include the amorphous indium tin oxide (ITO).

The anode electrode may further include an additional skin layer disposed under the additional blocking layer. The additional blocking layer may be interposed between the additional skin layer and the reflective layer. The additional skin layer may include the crystalline indium tin oxide (ITO).

According to an aspect of the present disclosure, there is provided a display device includes a substrate including a display area in which light emitting areas are arranged; a circuit layer disposed on the substrate; and an element layer disposed on the circuit layer. The element layer includes light emitting elements disposed in the light emitting areas, respectively. Each of the light emitting elements includes an anode electrode and a cathode electrode opposing each other, and a light emitting layer disposed between the anode electrode and the cathode electrode. The anode electrode includes a reflective layer disposed on the circuit layer and including a reflective metal material; a blocking layer disposed on the reflective layer; and a skin layer disposed on the blocking layer. The blocking layer includes amorphous indium tin oxide (ITO) containing silicon dioxide (SiO2). The skin layer includes crystalline indium tin oxide (ITO).

The reflective layer may include silver (Ag) or a silver alloy.

The content of silicon dioxide in the amorphous indium tin oxide may be in the range of about 1.0 wt % to about 10.0 wt % with respect to a total weight of the amorphous indium tin oxide.

A thickness of each of the blocking layer and the skin layer may be in the range of about 5 nm to about 10 nm. A thickness of the reflective layer may be in the range of about 80 nm to about 100 nm.

The anode electrode may further include an additional blocking layer disposed between the circuit layer and the reflective layer. The reflective layer may be interposed between the blocking layer and the additional blocking layer. The additional blocking layer includes the amorphous indium tin oxide (ITO).

The element layer may further include a pixel defining layer disposed in a non-light emitting area between the light emitting areas and covering an edge of the anode electrode. The light emitting layer may be disposed on the anode electrode, and the cathode electrode may be disposed on the light emitting layer and the pixel defining layer.

The substrate may further include a non-display area disposed around the display area; a hole area surrounded by the display area; and a hole peripheral area disposed between the hole area and the display area. The display device may further include a sealing layer disposed on the element layer; and a light transmitting hole formed in the hole area and penetrating through the circuit layer, the element layer, and the sealing layer.

The element layer may further include a first common layer disposed between the anode electrode and the light emitting layer; and a second common layer disposed between the light emitting layers and the cathode electrode. The circuit layer may include an interlayer-insulating layer disposed on the substrate; a first source drain conductive layer disposed on the interlayer-insulating layer; a first planarization layer covering the first source drain conductive layer; a second source drain conductive layer disposed on the first planarization layer; and a second planarization layer covering the second source drain conductive layer.

The display device may further include two or more roof portions disposed on the first source drain conductive layer in the hole peripheral area and disposed around the hole area; at least one undercut groove defined between the two or more roof portions in a plan view and formed in the first planarization layer. An undercut structure in which edges of the two or more roof portions protrude further than a side surface of the at least one undercut groove is formed between the two or more roof portions. The second common layer and the cathode electrode are each discontinued by the undercut structure.

According to an aspect of the present disclosure, there is provided an electronic device includes a display device providing a screen. The display device includes a substrate including a display area in which light emitting areas are arranged; a circuit layer disposed on the substrate; and an element layer disposed on the circuit layer. The element layer includes light emitting elements disposed in the light emitting areas, respectively. Each of the light emitting elements includes an anode electrode and a cathode electrode opposing each other, and a light emitting layer disposed between the anode electrode and the cathode electrode. The anode electrode includes a reflective layer disposed on the circuit layer and including a reflective metal material; a blocking layer disposed on the reflective layer; and a skin layer disposed on the blocking layer. The blocking layer includes amorphous indium tin oxide (ITO) containing silicon dioxide (SiO2). The skin layer includes crystalline indium tin oxide (ITO). The reflective layer includes silver (Ag) or a silver alloy.

The content of silicon dioxide in the amorphous indium tin oxide may be in the range of about 1.0 wt % to about 10.0 wt % with respect to a total weight of the amorphous indium tin oxide.

A thickness of each of the blocking layer and the skin layer may be in the range of about 5 nm to about 10 nm. A thickness of the reflective layer may be in the range of about 80 nm to about 100 nm.

The anode electrode may further include an additional blocking layer disposed between the circuit layer and the reflective layer. The reflective layer may be interposed between the blocking layer and the additional blocking layer. The additional blocking layer may include the amorphous indium tin oxide (ITO).

The light emitting element according to embodiments includes an anode electrode, a cathode electrode, and a light emitting layer disposed therebetween.

According to embodiments, the anode electrode may include a reflective layer including a reflective metal material, a blocking layer disposed on one surface of the reflective layer, and a skin layer disposed on the blocking layer.

The blocking layer may include amorphous indium tin oxide (ITO) containing silicon dioxide (SiO₂), and the skin layer may include crystalline indium tin oxide (ITO).

Since the indium tin oxide (ITO) of the blocking layer contains silicon dioxide, it may remain in an amorphous state without being completely crystallized even when exposed to heat. Accordingly, microscopic holes due to the deepened crystalline structure may not be formed in the blocking layer.

Therefore, even if the anode electrode is exposed to heat treatment and the crystallization of indium tin oxide included in the skin layer is deepened by the heat treatment, deformation of the reflective layer may be suppressed by the blocking layer.

As a result, the luminance and lifespan of the light emitting element may be prevented from being reduced. In addition, by including the light emitting element of which luminance and lifespan may be prevented from being reduced, the display quality and lifespan of the display device and the electronic device may be effectively improved.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to embodiments;

FIG. 2 is a plan view illustrating the display device of FIG. 1;

FIG. 3 is a cross-sectional view taken along line A-A′ of FIG. 2;

FIG. 4 is a layout view illustrating portion B of FIG. 2;

FIG. 5 is an equivalent circuit diagram illustrating a light emitting pixel driver of FIG. 4;

FIG. 6 is a cross-sectional view taken along line D-D′ of FIG. 4;

FIG. 7 is an enlarged view illustrating portion E of FIG. 6 according to an embodiment;

FIG. 8 is a simulation graph illustrating an elongation of indium tin oxide (ITO) according to the heat treatment time and heat treatment temperature;

FIGS. 9 and 10 are enlarged views illustrating portion F of FIG. 6 according to comparative examples;

FIG. 11 is an enlarged view illustrating portion F of FIG. 6 according to an embodiment;

FIG. 12 is a layout view illustrating portion C of FIG. 2;

FIG. 13 is a cross-sectional view taken along line G-G′ of FIG. 11;

FIGS. 14, 15, and 16 are process views illustrating a process of disposing an undercut groove and an element layer of FIG. 13; and

FIGS. 17 and 18 are enlarged views illustrating portion E of FIG. 6 according to embodiments.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above (i.e., view in a thickness direction (third direction DR3) of a display device 100), and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±10%, 5%, or 2% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

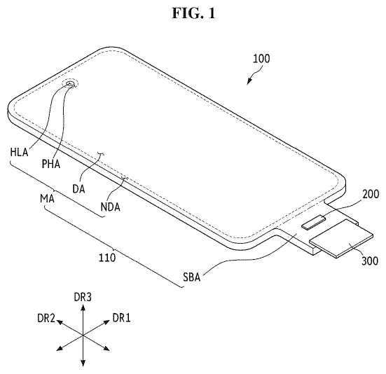

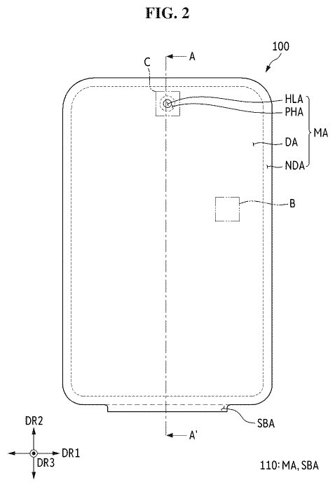

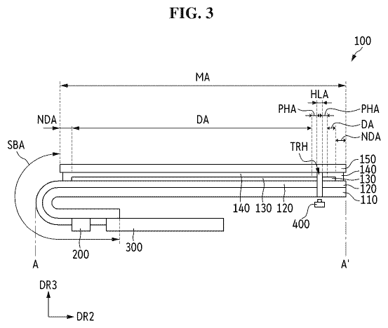

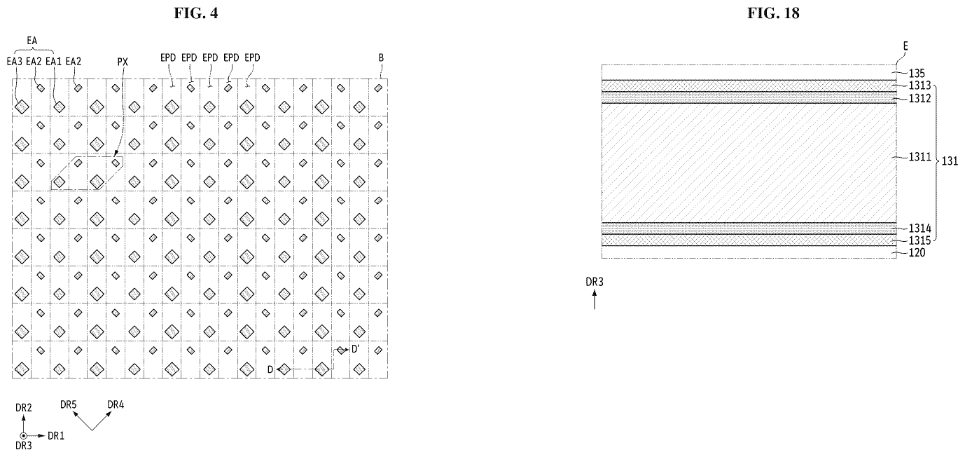

FIG. 1 is a perspective view illustrating a display device according to embodiments. FIG. 2 is a plan view illustrating the display device of FIG. 1. FIG. 3 is a cross-sectional view taken along line A-A′ of FIG. 2. FIG. 4 is a layout view illustrating portion B of FIG. 2.

Referring to FIGS. 1 and 2, a display device 100 is a device that displays a moving image or a still image, and may be used as a display screen of each of various products such as a television, a laptop computer, a monitor, a billboard, and an Internet of Things (IoT) device as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra-mobile PC (UMPC).

The display device 100 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, the description will be mainly made based on the fact that the display device 100 is an organic light emitting display device. However, the present disclosure is not limited thereto and may be applied to display devices including organic insulating materials, organic light emitting materials, and metal materials.

The display device 100 may be formed to be flat, but is not limited thereto. For example, the display device 100 may include curved surface portions formed at left and right distal ends thereof and having a constant curvature or a variable curvature. In addition, the display device 100 may be flexibly formed to be curved, bent, folded, or rolled.

As illustrated in FIGS. 1, 2, and 3, the display device 100 includes a substrate 110.

The substrate 110 may include a main area MA corresponding to a display surface of the display device 100 and a sub-area SBA protruding from one side of the main area MA.

As illustrated in FIG. 2, the main area MA may include a display area DA disposed at a center of the display surface of the display device 100 and a non-display area NDA disposed around the display area DA.

The display area DA may be formed in a rectangular plane having short sides extending in a first direction DR1 and long sides extending in a second direction DR2 intersecting the first direction DR1. A corner where the short side in the first direction DR1 and the long side in the second direction DR2 meet may be rounded to have a predetermined curvature or may be formed at a right angle. The planar shape of the display area DA is not limited to the quadrangular shape, and the display area DA may be formed in other polygonal, circular, or oval shapes.

The non-display area NDA may be disposed at an edge of the main area MA to surround the display area DA in a plan view.

The sub-area SBA may be an area protruding from the non-display area NDA of the main area MA to one side in the second direction DR2.

FIGS. 2 and 3 illustrate the display device 100 with a portion of the sub-area SBA curved.

As illustrated in FIGS. 2 and 3, as a portion of the sub-area SBA is deformed into a curved shape, another portion of the sub-area SBA may be disposed on a rear surface of the substrate 110 opposite to the display surface.

Referring to FIG. 3, the display device 100 according to embodiments includes a substrate 110, a circuit layer 120 disposed on the substrate 110, an element layer 130 disposed on the circuit layer 120, and a sealing layer 140 disposed on the element layer 130.

The display device 100 according to embodiments may further include a cover window 150 disposed on the sealing layer 140. The cover window 150 may be bonded to face the substrate 110. Alternatively, the cover window 150 may be coupled to a bracket under the rear surface of the substrate 110. The bracket may accommodate the substrate 110 and a display driving circuit 300.

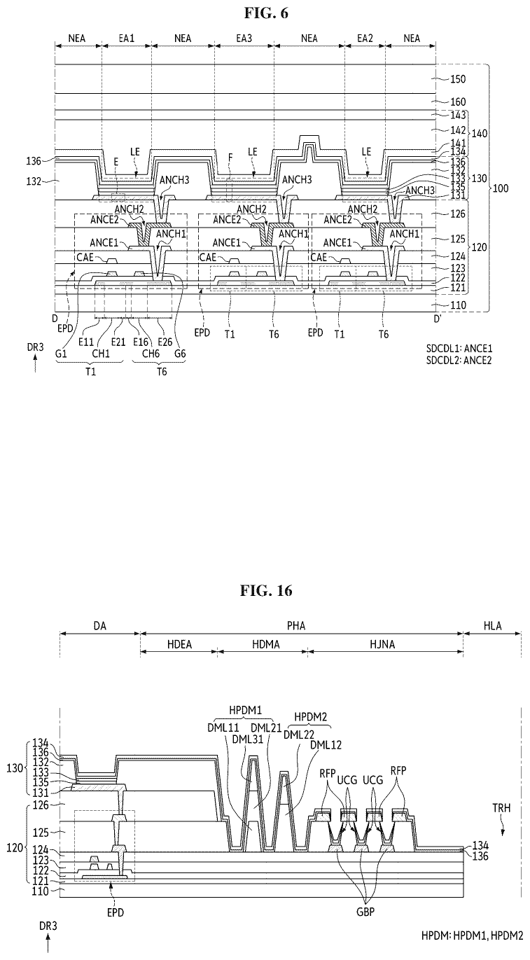

The display device 100 according to embodiments may further include a touch sensor layer (160 in FIG. 6) disposed on the sealing layer 140.

The display device 100 according to embodiments may further include a polarizing layer disposed on the sealing layer 140 to reduce reflection of external light.

The substrate 110 may be made of an insulating material such as a polymer resin. For example, the substrate 110 may be made of polyimide. The substrate 110 may be a flexible substrate that may be bent, folded, and rolled.

Alternatively, the substrate 110 may be made of an insulating material such as glass.

The substrate 110 may include a main area MA and a sub-area SBA. The main area MA may include a display area DA and a non-display area NDA.

The circuit layer 120 may include conductive layers, one or more semiconductor layers, and insulating layers interposed therebetween. The circuit layer 120 may include transistors formed with one or more semiconductor layers and one or more conductive layers, and signal lines each formed with at least one of the conductive layers.

The element layer 130 may include light emitting elements that emit light according to a driving current applied from the circuit layer 120.

The sealing layer 140 may cover the circuit layer 120 and the element layer 130 and may block permeation of oxygen or moisture into the element layer 130.

The cover window 150 may include a light transmitting material. The cover window 150 may be made of an inorganic material such as glass or be made of an organic material such as plastic or a polymer material.

Referring to FIG. 4, the display area DA of the substrate 110 of the display device 100 according to embodiments may include light emitting areas EA. In addition, the display area DA may further include a non-light emitting area disposed in a spaced portion between the light emitting areas EA.

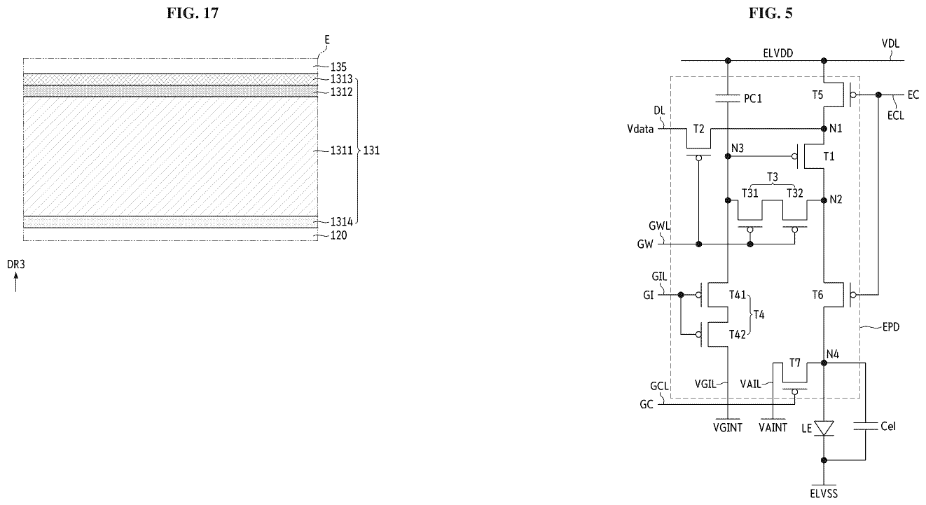

The element layer (130 in FIG. 3) may include light emitting elements (LE in FIG. 5) each disposed in the light emitting areas EA.

The circuit layer (120 in FIG. 3) may include light emitting pixel drivers EPD arranged to be parallel to each other in the first direction DR1 and the second direction DR2 in the main area MA. The light emitting pixel drivers EPD may be electrically connected to the light emitting element (LE in FIG. 5) of the element layer 130, respectively.

The light emitting areas EA may have a rhombic planar shape or a rectangular planar shape. However, this is only an example, and the planar shape of the light emitting areas EA according to an embodiment is not limited to that illustrated in FIG. 4. That is, the light emitting areas EA may have a polygonal planar shape such as a square, pentagon, or hexagon, or a circular or oval planar shape including curved edges.

According to embodiments, the light emitting areas EA may include a first light emitting area EA1 that emits light in a first wavelength band, a second light emitting area EA2 that emits light in a second wavelength band lower than the first wavelength band, and a third light emitting area EA3 that emits light in a third wavelength band lower than the second wavelength band.

As an example, the first wavelength band is about 600 nm to about 750 nm, and the light in the first wavelength band may be red. The second wavelength band is about 480 nm to about 560 nm, and the light in the second wavelength band may be green. The third wavelength band is about 370 nm to about 460 nm, and the light in the third wavelength band may be blue.

Accordingly, a unit pixel PX that displays white light may be provided by one or more first light emitting areas EA1, one or more second light emitting areas EA2, and one or more third light emitting areas EA3 adjacent to each other among the light emitting areas EA.

The first light emitting areas EA1 and the third light emitting areas EA3 may be alternately disposed in the first direction DR1 or the second direction DR2.

The second light emitting areas EA2 may be arranged to be parallel to each other in the first direction DR1 or the second direction DR2.

The second light emitting areas EA2 may be adjacent to the first light emitting areas EA1 and the third light emitting areas EA3 in diagonal directions DR4 and DR5 intersecting the first and second directions DR1 and DR2.

Pixels PX that display each luminance and color may be provided by the first light emitting area EA1, the second light emitting area EA2, and the third light emitting area EA3 adjacent to each other among the light emitting areas EA.

The pixels PX may be basic units that display various colors, including white, at predetermined luminance.

Each of the pixels PX may include at least one first light emitting area EA1, at least one second light emitting area EA2, and at least one third light emitting area EA3 adjacent to each other. Accordingly, each of the pixels PX may display various colors through mixing of light emitted from the first, second, and third light emitting areas EA1, EA2, and EA3 adjacent to each other.

FIG. 5 is an equivalent circuit diagram illustrating a light emitting pixel driver of FIG. 4.

Referring to FIG. 5, one of the light emitting elements LE of the element layer 130 may be electrically connected between one of the light emitting pixel drivers EPD of the circuit layer 120 and a second power ELVSS.

That is, an anode electrode of the light emitting element LE may be electrically connected to the light emitting pixel driver EPD, and the second power ELVSS having a lower voltage level than the first power ELVDD may be applied to a cathode electrode of the light emitting element LE.

A capacitor Cel connected in parallel with the light emitting element LE represents a parasitic capacitance between the anode electrode and the cathode electrode.

The circuit layer 120 may include a first power line VDL that transmits the first power ELVDD, a first initialization voltage line VGIL that transmits a first initialization voltage VGINT, and a second initialization voltage line VAIL that transmits a second initialization voltage VAINT.

The circuit layer 120 may further include a scan write line GWL that transmits a scan write signal GW, a scan initialization line GIL that transmits a scan initialization signal GI, an emission control line ECL that transmits an emission control signal EC, and a gate control line GCL that transmits a gate control signal GC.

One light emitting pixel driver EPD of the circuit layer 120 may include a first transistor T1 that generates a driving current for driving the light emitting element LE, two or more transistors T2 to T7 electrically connected to the first transistor T1 or the light emitting element LE, and at least one capacitor PC1.

The first transistor T1 may be disposed between a first node N1 and a second node N2.

A first electrode (e.g., a source electrode) of the first transistor T1 may be electrically connected to a first node N1, and may be electrically connected to the first power line VDL through the fifth transistor T5.

A second electrode (e.g., a drain electrode) of the first transistor T1 may be electrically connected to a second node N2, and may be electrically connected to an anode electrode of the light emitting element LE through the sixth transistor T6.

The second transistor T2 may be electrically connected between the data line DL and the first node N1.

That is, the first electrode of the first transistor T1 may be electrically connected to the data line DL through the second transistor T2.

The second transistor T2 may be turned on by the scan write signal GW of the scan write line GWL.

A gate electrode of the first transistor T1 may be electrically connected to a third node N3.

The first capacitor PC1 may be electrically connected between the third node N3 and the first power line VDL.

Accordingly, a potential of the gate electrode of the first transistor T1 may be maintained at a voltage charged in the first power line VDL.

In addition, when the data signal Vdata of the data line DL is transmitted to the first electrode of the first transistor T1 through a turned-on second transistor T2, a voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, that is, a gate-source voltage difference is a threshold voltage or more, the first transistor T1 may be turned on, thereby generating a drain-source current of the first transistor T1 corresponding to the data signal Vdata.

Subsequently, when the fifth transistor T5 and the sixth transistor T6 are turned on, the first transistor T1 may be connected in series with the light emitting element LE between the first power ELVDD and a second power ELVSS. Accordingly, the drain-source current of the first transistor T1 corresponding to the data signal Vdata may be supplied as a driving current of the light emitting element LE.

As a result, the light emitting element LE may emit light with luminance corresponding to the data signal Vdata.

The third transistor T3 may be disposed between the second node N2 and the third node N3. That is, the third transistor T3 may be electrically connected between the gate electrode of the first transistor T1 and the second electrode of the first transistor T1.

The third transistor T3 may include a plurality of sub-transistors connected in series with each other. As an example, the third transistor T3 may include a first sub-transistor T31 and a second sub-transistor T32.

A first electrode of the first sub-transistor T31 may be connected to the gate electrode of the first transistor T1, a second electrode of the first sub-transistor T31 may be connected to a first electrode of the second sub-transistor T32, and a second electrode of the second sub-transistor T32 may be connected to the second electrode of the first transistor T1.

In this way, the potential of the gate electrode of the first transistor T1 may be prevented from being changed due to a leakage current caused by a third transistor T3 that is not turned on.

The first sub-transistor T31 and the second sub-transistor T32 may be turned on by the scan write signal GW of the scan write line GWL.

When the first sub-transistor T31 and the second sub-transistor T32 are turned on, the voltage difference between the second node N2 and the third node N3 may be initialized.

The fourth transistor T4 may be electrically connected between the third node N3 and the first initialization voltage line VGIL. That is, the fourth transistor T4 may be connected between the gate electrode of the first transistor T1 and the first initialization voltage line VGIL.

The fourth transistor T4 may include a plurality of sub-transistors connected in series with each other. As an example, the fourth transistor T4 may include a third sub-transistor T41 and a fourth sub-transistor T42.

A first electrode of the third sub-transistor T41 may be connected to the gate electrode of the first transistor T1, a second electrode of the third sub-transistor T41 may be connected to a first electrode of the fourth sub-transistor T42, and a second electrode of the fourth sub-transistor T42 may be connected to the first initialization voltage line VGIL.

In this way, the potential of the gate electrode of the first transistor T1 may be prevented from being changed due to a leakage current caused by a fourth transistor T4 that is not turned on.

The third sub-transistor T41 and the fourth sub-transistor T42 may be turned on by the scan initialization signal GI of the scan initialization line GIL.

When the third sub-transistor T41 and the fourth sub-transistor T42 are turned on, the potential of the third node N3 may be initialized to the first initialization voltage VGINT.

The fifth transistor T5 may be electrically connected between the first node N1 and the first power line VDL.

The sixth transistor T6 may be electrically connected between the second node N2 and a fourth node N4.

The fourth node N4 may be electrically connected to the anode electrode of the light emitting element LE.

The fifth transistor T5 and the sixth transistor T6 may be turned on by the emission control signal EC of the emission control line ECL.

The seventh transistor T7 may be electrically connected between the fourth node N4 and the second initialization voltage line VAIL.

The seventh transistor T7 may be turned on by the gate control signal GC of the gate control line GCL.

A potential of the fourth node N4 may be initialized to the second initialization voltage VAINT through the turned-on seventh transistor T7.

According to embodiments, the first to seventh transistors T1 to T7 may be provided as P-type MOSFETs. Alternatively, the third transistor T3 and the fourth transistor T4 among the first to seventh transistors T1 to T7 may be provided as N-type MOSFETs rather than P-type MOSFETs.

FIG. 6 is a cross-sectional view taken along line D-D′ of FIG. 4.

Referring to FIG. 6, the display device 100 according to embodiments includes a substrate 110, a circuit layer 120 on the substrate 110, and an element layer 130 on the circuit layer 120.

The display device 100 according to embodiments may further include a sealing layer 140 on the element layer 130.

The display device 100 may further include a touch sensor layer 160 on the sealing layer 140, and a cover window 150 on the touch sensor layer 160.

The display device 100 may further include a polarizing layer disposed between the touch sensor layer 160 and the cover window 150.

According to embodiments, the circuit layer 120 may include an interlayer-insulating layer 124 disposed on the substrate 110, a first source drain conductive layers SDCDL1 disposed on the interlayer-insulating layer 124, a first planarization layer 125 covering the first source and drain conductive layer SDCDL1, a second source drain conductive layer SDCDL2 disposed on the first planarization layer 125, and a second planarization layer 126 covering the second source drain conductive layer SDCDL2.

In addition, the circuit layer 120 may further include a semiconductor layer disposed on the substrate 110, a first gate insulating layer 122 covering the semiconductor layer, a first gate conductive layer disposed on the first gate insulating layer 122, a second gate insulating layer 123 covering the first gate conductive layer, and a second gate conductive layer disposed on the second gate insulating layer 123.

The interlayer-insulating layer 124 may be disposed on the second gate insulating layer 123 and may cover the second gate conductive layers.

The circuit layer 120 may further include a buffer layer 121 covering the substrate 110.

In this case, the semiconductor layer may be disposed on the buffer layer 121.

According to embodiments, each of the light emitting pixel drivers EPD may include a first transistor T1, and second to seventh transistors (T2 to T7 in FIG. 5) and at least one capacitor (PC1 in FIG. 5) electrically connected to the first transistor T1 or the light emitting element (LE in FIG. 5).

FIG. 6 illustrates the first transistor T1, the sixth transistor T6, and the light emitting element LE of the light emitting pixel driver EPD of FIG. 5.

Each of the first transistor T1 and the sixth transistor T6 may include channel portions CH1 and CH6, first electrode portions E11 and E16, and second electrode portions E21 and E26 disposed on the semiconductor layer on the buffer layer 121.

In each of the first transistor T1 and the sixth transistor T6, the first electrode portions E11 and E16 may be connected to one end of the channel portions CH1 and CH6, and the second electrode portions E21 and E26 may be connected to other ends of the channel portions CH1 and CH6.

The second electrode portion E21 of the first transistor T1 may be connected to the first electrode portion E16 of the sixth transistor T6.

The first gate conductive layer on the first gate insulating layer 122 may include gate electrodes G1 and G6 of each of the first and sixth transistors T1 and T6.

In each of the first transistor T1 and the sixth transistor T6, the gate electrodes G1 and G6 may overlap the channel portions CH1 and CH6.

Since the second transistor (T2 in FIG. 5), the first sub-transistor (T31 in FIG. 5), the second sub-transistor (T32 in FIG. 5), the third sub-transistor (T41 in FIG. 5), the fourth sub-transistor (T42 in FIG. 5), the fifth transistor (T5 in FIG. 5), and the seventh transistor (T7 in FIG. 5) of the light emitting pixel driver EPD are provided as the same P-type MOSFET as the first transistor T1 and the sixth transistor T6, the overlapping descriptions will be omitted below.

The second gate conductive layer on the second gate insulating layer 123 may include a capacitor electrode CAE that overlaps the gate electrode G1 of the first transistor T1.

The capacitor electrode CAE may be electrically connected to the first power line (VDL in FIG. 5). Accordingly, a first capacitor (PC1 in FIG. 5) may be provided by an overlapping area between the capacitor electrode CAE and the gate electrode G1 of the first transistor T1.

The first source drain conductive layer SDCDL1 on the interlayer-insulating layer 124 may include a first anode connection electrode ANCE1.

The first anode connection electrode ANCE1 may be electrically connected to the second electrode portion E26 of the sixth transistor T6 through a first anode connection hole ANCH1.

The second source drain conductive layer SDCDL2 on the first planarization layer 125 may include a second anode connection electrode ANCE2.

The second anode connection electrode ANCE2 may be electrically connected to the first anode connection electrode ANCE1 through a second anode connection hole ANCH2.

The anode electrode 131 of the element layer 130 may be disposed on the second planarization layer 126, and may be electrically connected to the second anode connection electrode ANCE2 through a third anode connection hole ANCH3.

As a result, the anode electrode 131 may be electrically connected to the second electrode portion E26 of the sixth transistor T6 through the first anode connection electrode ANCE1 and the second anode connection electrode ANCE2.

The element layer 130 may be disposed on the second planarization layer 126 of the circuit layer 120.

The element layer 130 may include light emitting elements LE disposed in the light emitting areas EA1, EA2, and EA3, respectively.

Each of the light emitting elements LE may include an anode electrode 131 and a cathode electrode 134 opposing each other, and a light emitting layer 133 disposed between the anode electrode 131 and the cathode electrode 134.

In addition, each of the light emitting elements LE may further include first common layers 135 disposed between the anode electrodes 131 and the light emitting layers 133, and a second common layer 136 disposed between the light emitting layers 133 and the cathode electrode 134.

According to embodiments, the element layer 130 may include anode electrodes 131 each disposed in the light emitting areas EA1, EA2, and EA3, a pixel defining layer 132 disposed in the non-light emitting area NEA between the light emitting areas EA1, EA2, and EA3 and covering edges of the anode electrodes 131, light emitting layers 133 each disposed on the anode electrodes 131, and a cathode electrode 134 disposed on the light emitting layers 133 and the pixel defining layer 132.

The element layer 130 may further include a spacer layer 132′ disposed on a portion of the pixel defining layer 132. In this case, the cathode electrode 134 may be further disposed on the spacer layer 132′.

The first common layers 135 may be respectively disposed on the anode electrodes 131.

The second common layer 136 may cover the light emitting layers 133, the pixel defining layer 132, and the spacer layer 132′, and may be disposed under the cathode electrode 134.

That is, the second common layer 136 may be entirely disposed over the display area DA including not only the light emitting areas EA but also the non-light emitting area NEA between the light emitting areas EA.

The sealing layer 140 may be disposed on the circuit layer 120 and cover the element layer 130.

The sealing layer 140 is used to block permeation of oxygen or moisture into the element layer 130 and to relieve electrical or physical shock to the circuit layer 120 and the element layer 130.

The sealing layer 140 may include a first sealing layer 141 disposed on the element layer 130 and including an inorganic insulating material, a second sealing layer 142 disposed on the first sealing layer 141, overlapping the display area DA, and including an organic insulating material, and a third sealing layer 143 covering the second sealing layer 142 and including an inorganic insulating material.

The touch sensor layer 160 may be disposed on the sealing layer 140. The touch sensor layer 160 may include touch electrodes for detecting a signal that varies depending on a touch of a person or object and sensing a point in the main area MA where the touch of the person or object occurred.

The cover window 150 may be disposed on the touch sensor layer 160.

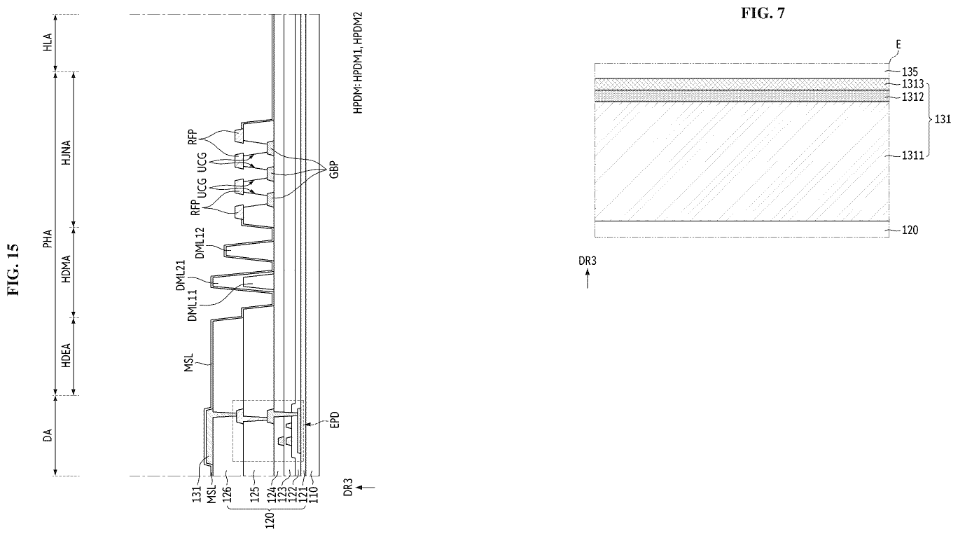

FIG. 7 is an enlarged view illustrating portion E of FIG. 6 according to an embodiment.

As illustrated in FIG. 7, according to an embodiment, the anode electrode 131 of the light emitting element (LE in FIG. 6) may include a reflective layer 1311, a blocking layer 1312 disposed on one surface (e.g., upper surface) of the reflective layer 1311, and a skin layer 1313 disposed on the blocking layer 1312.

The reflective layer 1311 may be disposed on the circuit layer 120.

The reflective layer 1311 may include a reflective metal material.

As an example, the reflective layer 1311 may include silver (Ag) or an alloy containing silver (Ag).

Considering the resistance and reflectivity of the anode electrode 131 and slimming of the display device 100, a thickness of the reflective layer 1311 may be in the range of about 80 nm to about 100 nm.

The blocking layer 1312 is intended to suppress deformation of the metal material of the reflective layer 1311, and may be disposed on the reflective layer 1311 and may include amorphous indium tin oxide (ITO).

The indium tin oxide (ITO) of the blocking layer 1312 may contain silicon dioxide (SiO₂) to maintain an amorphous state.

That is, the blocking layer 1312 may include amorphous indium tin oxide (ITO) containing silicon dioxide (SiO₂). In an embodiment, the blocking layer 1312 may not include crystalline indium tin oxide (ITO).

According to an embodiment, the content of silicon dioxide (SiO₂) in the amorphous indium tin oxide (ITO) may be in a range of about 1.0 wt % (weight ratio) to about 10.0 wt % with respect to a total weight of the amorphous indium tin oxide.

When the content of silicon dioxide (SiO₂) in the indium tin oxide (ITO) is smaller than about 1.0 wt %, crystallization of the indium tin oxide (ITO) may not be suppressed.

When the content of silicon dioxide (SiO₂) in the indium tin oxide (ITO) exceeds about 10.0 wt %, an insulating property of the indium tin oxide (ITO) may increase, thereby increasing the resistance of the anode electrode 131.

Considering deformation suppression of the reflective layer 1311 and resistance of the anode electrode 131, a thickness of the blocking layer 1312 may be in the range of about 5 nm to about 10 nm.

The skin layer 1313 becomes a surface of the anode electrode 131, and is intended to prevent the reflective layer 1311 and the blocking layer 1312 from being directly exposed to heat treatment or etching materials.

The skin layer 1313 may include a conductive material having a relatively high etching ratio.

As an example, the skin layer 1313 may include crystalline indium tin oxide (ITO). In an embodiment, the skin layer 1313 may not include amorphous indium tin oxide (ITO).

Considering an etching margin and resistance of the anode electrode 131, a thickness of the skin layer 1313 may be in the range of about 5 nm to about 10 nm.

The indium tin oxide (ITO) of the skin layer 1313 may be more strongly crystallized by repeatedly expanding or contracting when exposed to heat treatment or etching materials. As a result, a surface uniformity of the anode electrode 131 may be effectively improved.

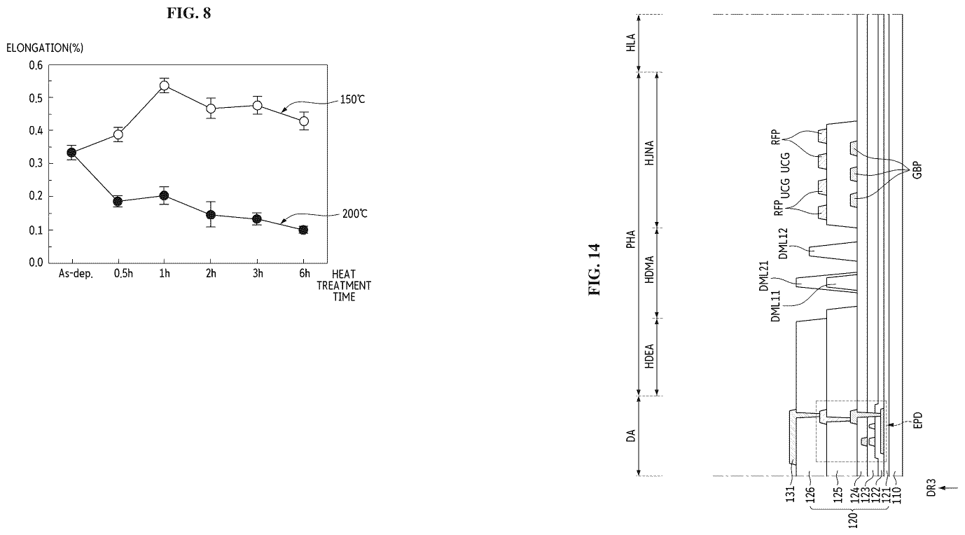

FIG. 8 is a simulation graph illustrating an elongation of indium tin oxide (ITO) according to the heat treatment time and heat treatment temperature.

As illustrated in FIG. 8, since indium tin oxide (ITO) is deformed into a crystalline state by a high temperature environment of 200 degrees in Celsius (° C.) or higher, an elongation of indium tin oxide (ITO) is reduced.

In addition, the longer the crystalline indium tin oxide (ITO) is exposed to a high temperature environment, the more severe the crystallization becomes, the elongation of indium tin oxide (ITO) is further reduced.

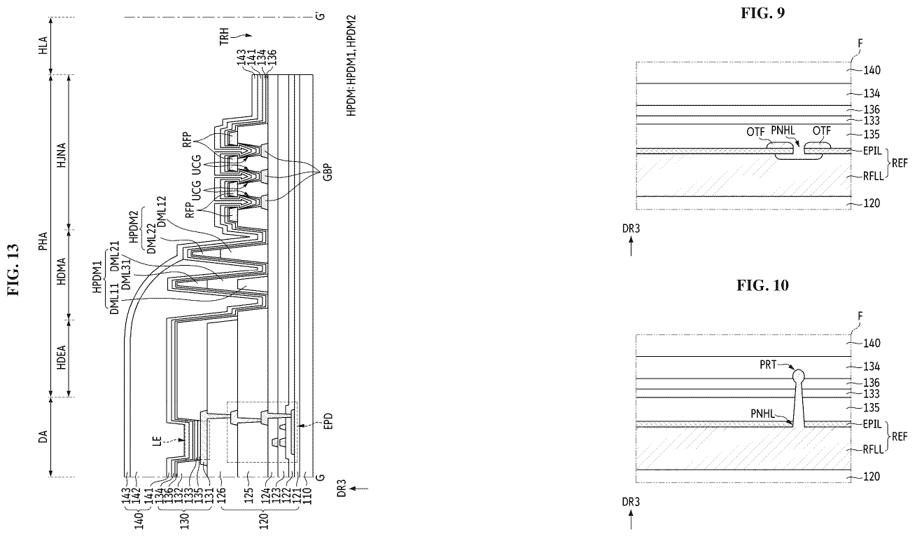

FIGS. 9 and 10 are enlarged views illustrating portion F of FIG. 6 according to comparative examples.

Referring to FIGS. 9 and 10, an anode electrode REF according to a comparative example does not include the blocking layer (1312 in FIG. 7), and only includes a reflective layer RFLL and a skin layer EPIL disposed on one surface of the reflective layer RFLL.

The skin layer EPIL includes crystalline indium tin oxide (ITO).

The more crystalline indium tin oxide (ITO) is exposed to heat treatment or etching materials, the more the crystallization of the indium tin oxide (ITO) becomes severe, microscopic holes (hereinafter, referred to as pin holes PNHL) may be formed in the indium tin oxide (ITO).

Accordingly, as illustrated in FIG. 9, a metal material OTF of the reflective layer RFLL may leak out of the skin layer EPIL through the pin hole PNHL of the skin layer EPIL. In addition, due to the leakage of the metal material OTF, the reflective layer RFLL may be partially deformed into a concave shape. In this case, luminance of the light emitting element (LE in FIG. 6) may be reduced.

Alternatively, as illustrated in FIG. 10, as the reflective layer RFLL partially expands and the metal material of the reflective layer RFLL protrudes through the pin hole PNHL of the skin layer EPIL, a protruding portion PRT of the metal material may be formed.

When the protruding portion PRT of the metal material is adjacent to the cathode electrode 134, the light emitting element LE may be damaged due to a short circuit defect between the anode electrode REF and the cathode electrode 134, resulting in a dark spot defect.

Meanwhile, as illustrated in FIG. 8, the indium tin oxide (ITO) may not be completely crystallized in an environment of 150° C. or less. That is, in the environment of 150° C. or less, some of the indium tin oxide (ITO) may be deformed into a crystalline state, while others may remain in an amorphous state.

In this way, the elongation of indium tin oxide (ITO) partially including the amorphous state is higher than the elongation of the crystalline indium tin oxide (ITO) without the amorphous state.

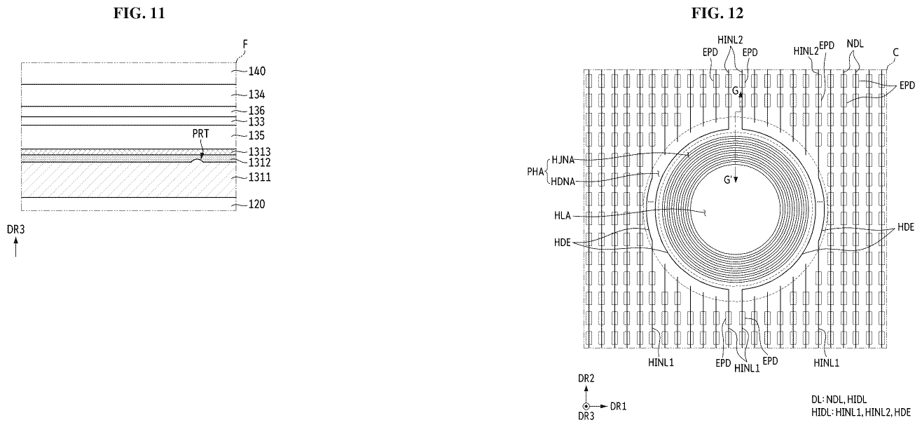

FIG. 11 is an enlarged view illustrating portion F of FIG. 6 according to an embodiment.

As illustrated in FIG. 11, the anode electrode 131 according to an embodiment includes a blocking layer 1312 interposed between the reflective layer 1311 and the skin layer 1313 and including amorphous indium tin oxide (ITO).

Accordingly, even if the reflective layer 1311 expands and partially protrudes PRT due to heat treatment, etc., the protruding portion PRT of the reflective layer 1311 may be blocked by a high elongation of the blocking layer 1312 and may not extend to the skin layer 1313.

That is, deformation of the reflective layer 1311 and resulting deformation of the skin layer 1313 may be suppressed by the blocking layer 1312.

Therefore, the reduction in luminance and lifespan of the light emitting element (LE in FIG. 6) may be prevented.

In addition, the display quality and lifespan of the display device 100 including the light emitting element LE may be improved.

FIG. 12 is a layout view illustrating portion C of FIG. 2.

As illustrated in FIG. 2, the substrate (110 in FIG. 3) of the display device 100 according to embodiments may include a hole area HLA surrounded by the display area DA, and a hole peripheral area PHA disposed between the hole area HLA and the display area DA in a plan view.

As illustrated in FIG. 3, a light transmitting hole TRH penetrating through the substrate 110, the circuit layer 120, the element layer 130, and the sealing layer 140 may be disposed in the hole area HLA.

Referring to FIG. 12, the hole area HLA may be surrounded by the display area DA of the main area MA.

The hole peripheral area PHA may include a hole peripheral junction area HJNA disposed around the hole area HLA.

The hole peripheral area PHA may further include a hole peripheral bypass area HDEA disposed between the display area DA and the hole peripheral junction area HJNA.

The display device 100 according to embodiments may include two or more roof portions RFP disposed in the hole peripheral junction area HJNA of the hole peripheral area PHA and arranged around the hole area HLA.

As the second common layer (136 in FIG. 6) and the cathode electrode (134 in FIG. 6) of the element layer (130 in FIG. 10) are entirely disposed in the display area DA, the second common layer (136 in FIG. 6) and the cathode electrode (134 in FIG. 6) may also be disposed in the hole peripheral area PHA surrounded by the display area DA in a plan view.

The roof portions RFP disposed in the hole peripheral junction area HJNA are intended to provide an undercut structure for separating the second common layer (136 in FIG. 6) and the cathode electrode (134 in FIG. 6) in the hole peripheral junction area HJNA.

According to embodiments, the circuit layer (120 in FIG. 3) may include light emitting pixel drivers EPD arranged in the first direction DR1 and the second direction DR2 in the display area DA, and data lines DL that extend in the second direction DR2 and transmit the data signals (Vdata in FIG. 5) to the light emitting pixel drivers EPD.

As the light emitting pixel drivers EPD are arranged on both sides of the hole peripheral area PHA in the second direction DR2, the data lines DL may include hole intersecting data lines HIDL that intersect the hole area HLA or the hole peripheral area PHA.

That is, the data lines DL may include hole intersecting data lines HIDL that intersect the hole area HLA or the hole peripheral area PHA, and normal data lines NDL except for the hole intersecting data lines HIDL.

Each of the hole interesting data lines HIDL may include a first hole separation line HINL1 facing one side of the hole peripheral area PHA in the second direction DR2, a second hole separation line HINL2 facing the other side of the hole peripheral area PHA in the second direction DR2, and a hole bypass line HDE disposed in the hole peripheral area PHA and electrically connecting between the first hole separation line HINL1 and the second hole separation line HINL2.

The hole bypass line HDE may be disposed in a hole peripheral bypass area HDEA of the hole peripheral area PHA and may be in a shape of a curved arc.

Each of the normal data lines NDL may be provided in the form that does not intersect the hole area HLA and the hole peripheral area PHA and does not include a curved hole bypass line HDE disposed in the hole peripheral area PHA.

According to embodiments, the circuit layer 120 may further include dummy light emitting pixel drivers disposed closest to the hole peripheral area PHA.

The dummy light emitting pixel drivers may have the same structure as the light emitting pixel drivers EPD, except that they are not electrically connected to the light emitting elements (LE in FIG. 5) of the element layer (130 in FIG. 3).

Since physical or chemical shocks that occur during the process of disposing the light transmitting hole (TRH in FIG. 3) in the hole area HLA may be cushioned by the dummy light emitting pixel drivers, the possibility of damage to the light emitting pixel drivers EPD may be reduced.

FIG. 13 is a cross-sectional view taken along line G-G′ of FIG. 11.

Referring to FIG. 13, the display device 100 according to embodiments may include two or more roof portions RFP disposed in the hole peripheral junction area HJNA of the hole peripheral area PHA and arranged around the hole area HLA, and at least one undercut groove UCG disposed between the two or more roof portions RFP and formed in the first planarization layer 125.

The two or more roof portions RFP may be disposed on the second source drain conductive layer (SDCDL2 in FIG. 6) on the first planarization layer 125.

The at least one undercut groove UCG may penetrate through at least a portion of the first planarization layer 125.

According to embodiments, in order to prevent damage to the interlayer-insulating layer 124 by the at least one undercut groove UCG, the display device 100 may further include at least one groove bottom portion GBP disposed on the first source drain conductive layer (SDCDL1 of FIG. 6) on the interlayer-insulating layer 124 and overlapping the at least one undercut groove UCG.

The at least one undercut groove UCG may extend until it reaches the at least one groove bottom portion GBP.

As edges of the two or more roof portions RFP protrude further than a side surface of the at least one undercut groove UCG between the two or more roof portions RFP, an undercut structure may be formed.

Accordingly, the second common layer 136 and the cathode electrode 134 which are entirely disposed in the display area DA may be separated by the undercut structure between the two or more roof portions RFP and the at least one undercut groove UCG.

That is, some portions of the second common layer 136 disposed on the two or more roof portions RFP may be separated from other portions disposed within the at least one undercut groove UCG.

In addition, some portions of the cathode electrode 134 disposed on the two or more roof portions RFP may be separated from other portions disposed within the at least one undercut groove UCG.

In this way, the occurrence of a path through which oxygen or moisture permeates from the light transmitting hole TRH of the hole area HLA to the display area DA through the second common layer 136 and the cathode electrode 134 exposed through the light transmitting hole TRH of the hole area HLA may be delayed or reduced.

The display device 100 according to embodiments may further include at least one hole peripheral dam portion HPDM disposed in a hole peripheral dam area HDMA between two or more roof portions RFP of the hole peripheral area PHA and the hole peripheral bypass area HDEA.

The at least one hole peripheral dam portion HPDM may be a barrier that blocks the second sealing layer 142 of the sealing layer 140 including the organic material from diffusing into the hole area HLA.

The hole peripheral dam area HDMA of the hole peripheral area PHA may be disposed between the hole peripheral bypass area HDEA and the hole peripheral junction area HJNA so that the hole bypass line HDE disposed in the hole peripheral bypass area HDEA may be protected by the second sealing layer 142.

Each of at least one hole peripheral dam portion HPDM may include two or more dam layers DML11, DML21, and DML31 and DML12 and DML22.

Each of the two or more dam layers DML11, DML21, and DML31 and DML12 and DML22 may be disposed on the same layer as one of the first planarization layer 125, the second planarization layer 126, the pixel defining layer 132, and the spacer layer 132′.

As an example, at least one hole peripheral dam portion HPDM may include a first hole peripheral dam portion HPDM1 adjacent to the hole peripheral bypass area HDEA, and a second hole peripheral dam portion HPDM1 adjacent to the hole peripheral junction area HJNA.

The first hole peripheral dam portion HPDM1 may include a first dam layer DML11, which is the same layer as the first planarization layer 125, a second dam layer DML21, which is the same layer as the second planarization layer 126, and a third dam layer DML31, which is the same layer as the pixel defining layer 132.

The second hole peripheral dam portion HPDM2 may include a first dam layer DML12, which is the same layer as the second planarization layer 126 and a second dam layer DML22, which is the same layer as the pixel defining layer 132.

The sealing layer 140 may include a first sealing layer 141 disposed on the element layer 130, a second sealing layer 142 disposed on the first sealing layer 141 and overlapping the display area DA, and a third sealing layer 143 disposed on the first sealing layer 141 and covering the second sealing layer 142.

The second sealing layer 142 may include an organic insulating material, extend to at least one hole peripheral dam portion HPDM, and be spaced apart from the hole area HLA.

Each of the first sealing layer 141 and the third sealing layer 143 may include an inorganic insulating material.

Since the second sealing layer 142 extends to the at least one hole peripheral dam portion HPDM, the first sealing layer 141 and the third sealing layer 143 may be in contact with each other in the hole peripheral junction area HJNA between the hole area HLA and at least one hole peripheral dam portion HPDM of the hole peripheral area PHA.

In the hole peripheral junction area HJNA, the first sealing layer 141 may be in contact with two or more roof portions RFP by the undercut structure.

The circuit layer 120 may include a buffer layer 121 disposed on the substrate 110, a first gate insulating layer 122 disposed on the buffer layer 121, a second gate insulating layer 123 disposed on the first gate insulating layer 122, and an interlayer-insulating layer 124 disposed on the second gate insulating layer 123.

Each of the buffer layer 121, the first gate insulating layer 122, the second gate insulating layer 123, and the interlayer-insulating layer 124 may include an inorganic insulating material.

Each of the second common layer 136 and the cathode electrode 134 may be entirely disposed in the display area DA.

Each of the first sealing layer 141 and the third sealing layer 143 may include an inorganic insulating material and may be entirely disposed in the display area DA.

Accordingly, the light transmitting hole TRH of the hole area HLA may penetrate through the third sealing layer 143 and the first sealing layer 141 of the sealing layer 140, the cathode electrode 134 and the second common layer 136 of the element layer 130, and the interlayer-insulating layer 124, the second gate insulating layer 123, the first gate insulating layer 122, and the buffer layer 121 of the circuit layer 120.

The light transmitting hole TRH may further penetrate through the substrate 110.

FIGS. 14, 15, and 16 are process views illustrating a process of disposing an undercut groove and an element layer of FIG. 13.

Referring to FIG. 14, in a process of disposing the first source drain conductive layer (SDCDL1 in FIG. 6) on the interlayer-insulating layer 124 during the process of disposing the circuit layer 120, at least one hole bottom portion GBP may be disposed in the hole peripheral junction area HJNA.

In a process of disposing the first planarization layer 125 and a process of disposing the second anode connection hole (ANCH2 in FIG. 6), a first dam layer DML11 of the first hole peripheral dam portion (HPDM1 in FIG. 13) may be disposed in the hole peripheral dam area HDMA.

In a process of disposing the second source drain conductive layer (SDCDL2 in FIG. 6) on the first planarization layer 125, two or more roof portions RFP may be disposed in the hole peripheral junction area HJNA.

In a process of disposing the second planarization layer 126 and a process of disposing the third anode connection hole (ANCH3 in FIG. 6), a second dam layer DML21 of the first hole peripheral dam portion (HPDM1 in FIG. 13) and a first dam layer DML12 of the second hole peripheral dam portion (HPDM2 in FIG. 13) may be disposed in the hole peripheral dam area HDMA.

Referring to FIG. 15, after the process of disposing the anode electrode 131 during the process of disposing the element layer 130, a mask layer MSL may be disposed to cover the remaining area except for two or more roof portions RFP and the gap area between the two or more roof portions RFP in the main area MA.

In addition, by partially removing portions between the two or more roof portions RFP of the first planarization layer 125 by the mask layer MSL, at least one undercut groove UCG may be disposed.

Here, as edges of the two or more roof portions RFP protrude to at least one undercut groove UCG, an undercut structure may be provided.

Referring to FIG. 16, after the at least one undercut groove UCG is disposed, the mask layer (MSL in FIG. 15) is removed, and subsequently, first common layers 135 and light emitting layers 133 may be disposed in the light emitting areas (EA1, EA2, and EA3 in FIG. 6), and a second common layer 136 and a cathode electrode 134 may be entirely disposed in the display area DA.

Since the hole peripheral area PHA and the hole area HLA are disposed within the display area DA, the second common layer 136 and the cathode electrode 134 may also be disposed in the hole peripheral area PHA and the hole area HLA.

In addition, the second common layer 136 and the cathode electrode 134 may be separated by the undercut structure between the two or more roof portions RFP and the at least one undercut groove UCG.

As described above, in order to dispose the undercut structure in the hole peripheral junction area HJNA, the mask layer (MSL in FIG. 15) is used, and then the mask layer MSL is removed before disposing the first common layers 135.

Accordingly, the anode electrodes 131 may be exposed to heat treatment or etching materials in each of the process of disposing the anode electrodes 131, the process of disposing the pixel defining layer 132, and the process of removing the mask layer MSL.

However, according to embodiments, each of the anode electrodes 131 of the element layer 130 may maintain a relatively low surface roughness even when exposed to the heat treatment or etching materials because of including the skin layer 1313 including crystalline indium tin oxide (ITO).

In addition, each of the anode electrodes 131 of the element layer 130 includes the blocking layer 1312 disposed between the skin layer 1313 and the reflective layer 1311 and including amorphous indium tin oxide (ITO), thereby blocking deformation of the reflective layer 1311 including a metal material that shrinks or expands due to heat treatment from being transmitted to the skin layer 1313.

Therefore, since the reduction in luminance and lifespan of the light emitting element LE due to the deformation of the anode electrode 131 may be prevented, the display quality and lifespan of the display device 100 including the light emitting element LE may be improved.

FIGS. 17 and 18 are enlarged views illustrating portion E of FIG. 6 according to embodiments.

Since a display device 100 according to an embodiment illustrated in FIG. 17 is substantially the same as the display devices 100 according to the embodiments illustrated in FIGS. 1 to 16, except that the anode electrode 131 of the light emitting element LE further includes an additional blocking layer 1314 disposed under a bottom surface of the reflective layer 1311, the overlapping descriptions will be omitted below

Like the blocking layer 1312, the additional blocking layer 1314 may include amorphous indium tin oxide (ITO) containing silicon dioxide (SiO₂).

A thickness of the additional blocking layer 1314 may range from about 5 nm to about 10 nm.

By the additional blocking layer 1314, deformation of the reflective layer 1311 may be prevented from being transmitted to the circuit layer 120.

Therefore, since damage to the circuit layer 120 due to deformation of the anode electrode 131 may be prevented, the display quality and lifespan of the display device 100 may be improved.

Since a display device 100 according to an embodiment illustrated in FIG. 18 is substantially the same as the embodiment illustrated in FIG. 17 except that the anode electrode 131 of the light emitting element LE further includes an additional skin layer 1315 disposed under the additional blocking layer 1314, the overlapping description will be omitted below.

Like the skin layer 1313, the additional skin layer 1315 may include crystalline indium tin oxide (ITO).

A thickness of the additional skin layer 1315 may range from about 5 nm to about 10 nm.

However, the effects of the present disclosure are not restricted to the one set forth herein. The above and other effects of the present disclosure will become more apparent to one of daily skill in the art to which the present disclosure pertains by referencing the claims.

What is claimed is:

1. A light emitting element comprising:
an anode electrode and a cathode electrode opposing each other; and
a light emitting layer disposed between the anode electrode and the cathode electrode,
wherein the anode electrodes include:
a reflective layer including a reflective metal material;
a blocking layer disposed on a top surface of the reflective layer; and
a skin layer disposed on the blocking layer.

2. The light emitting element of claim 1, wherein the blocking layer includes amorphous indium tin oxide (ITO) containing silicon dioxide (SiO₂), and
the skin layer includes crystalline indium tin oxide (ITO).

3. The light emitting element of claim 2, wherein content of silicon dioxide in the amorphous indium tin oxide is in a range of about 1.0 weight percent (wt %) to about 10.0 wt % with respect to a total weight of the amorphous indium tin oxide.

4. The light emitting element of claim 2, wherein the reflective layer includes silver (Ag) or a silver alloy.

5. The light emitting element of claim 2, wherein a thickness of each of the blocking layer and the skin layer is in a range of about 5 nanometers (nm) to about 10 nm, and
a thickness of the reflective layer is in a range of about 80 nm to about 100 nm.

6. The light emitting element of claim 2, wherein the anode electrode further includes an additional blocking layer disposed under a bottom surface of the reflective layer,
the reflective layer is interposed between the blocking layer and the additional blocking layer, and
the additional blocking layer includes the amorphous indium tin oxide (ITO).

7. The light emitting element of claim 6, wherein the anode electrode further includes an additional skin layer disposed under the additional blocking layer,
the additional blocking layer is interposed between the additional skin layer and the reflective layer, and
the additional skin layer includes the crystalline indium tin oxide (ITO).

8. A display device comprising:
a substrate including a display area in which light emitting areas are arranged;
a circuit layer disposed on the substrate; and
an element layer disposed on the circuit layer,
wherein the element layer includes light emitting elements disposed in the light emitting areas, respectively,
each of the light emitting elements includes an anode electrode and a cathode electrode opposing each other, and a light emitting layer disposed between the anode electrode and the cathode electrode,
the anode electrode includes:
a reflective layer disposed on the circuit layer and including a reflective metal material;
a blocking layer disposed on the reflective layer; and
a skin layer disposed on the blocking layer,
the blocking layer includes amorphous indium tin oxide (ITO) containing silicon dioxide (SiO2), and
the skin layer includes crystalline indium tin oxide (ITO).

9. The display device of claim 8, wherein the reflective layer includes silver (Ag) or a silver alloy.

10. The display device of claim 8, wherein content of silicon dioxide in the amorphous indium tin oxide is in a range of about 1.0 wt % to about 10.0 wt % with respect to a total weight of the amorphous indium tin oxide.

11. The display device of claim 8, wherein a thickness of each of the blocking layer and the skin layer is in a range of about 5 nm to about 10 nm, and
a thickness of the reflective layer is in a range of about 80 nm to about 100 nm.

12. The display device of claim 8, wherein the anode electrode further includes an additional blocking layer disposed between the circuit layer and the reflective layer,
the reflective layer is interposed between the blocking layer and the additional blocking layer, and
the additional blocking layer includes the amorphous indium tin oxide (ITO).

13. The display device of claim 8, wherein the element layer further includes:
a pixel defining layer disposed in a non-light emitting area between the light emitting areas and covering an edge of the anode electrode,
wherein the light emitting layer is disposed on the anode electrode, and
the cathode electrode is disposed on the light emitting layer and the pixel defining layer.

14. The display device of claim 13, wherein the substrate further includes:
a non-display area disposed around the display area;
a hole area surrounded by the display area; and
a hole peripheral area disposed between the hole area and the display area;
wherein the display device further includes:
a sealing layer disposed on the element layer; and
a light transmitting hole formed in the hole area and penetrating through the circuit layer, the element layer, and the sealing layer.

15. The display device of claim 14, wherein the element layer further includes:
a first common layer disposed between the anode electrode and the light emitting layer; and
a second common layer disposed between the light emitting layers and the cathode electrode, and
the circuit layer includes:
an interlayer-insulating layer disposed on the substrate;
a first source drain conductive layer disposed on the interlayer-insulating layer;
a first planarization layer covering the first source drain conductive layer;
a second source drain conductive layer disposed on the first planarization layer; and
a second planarization layer covering the second source drain conductive layer.

16. The display device of claim 15, further comprising:
two or more roof portions disposed on the first source drain conductive layer in the hole peripheral area and disposed around the hole area;
at least one undercut groove defined between the two or more roof portions in a plan view and formed in the first planarization layer,
wherein an undercut structure in which edges of the two or more roof portions protrude further than a side surface of the at least one undercut groove is formed between the two or more roof portions, and
the second common layer and the cathode electrode are each discontinued by the undercut structure.

17. An electronic device comprising:
a display device providing a screen,
wherein the display device includes:
a substrate including a display area in which light emitting areas are arranged;
a circuit layer disposed on the substrate; and
an element layer disposed on the circuit layer,
the element layer includes light emitting elements disposed in the light emitting areas, respectively,
each of the light emitting elements includes an anode electrode and a cathode electrode opposing each other, and a light emitting layer disposed between the anode electrode and the cathode electrode,
the anode electrode includes:
a reflective layer disposed on the circuit layer and including a reflective metal material;
a blocking layer disposed on the reflective layer; and
a skin layer disposed on the blocking layer,
the blocking layer includes amorphous indium tin oxide (ITO) containing silicon dioxide (SiO₂), and
the skin layer includes crystalline indium tin oxide (ITO), and
the reflective layer includes silver (Ag) or a silver alloy.

18. The electronic device of claim 17, wherein content of silicon dioxide in the amorphous indium tin oxide is in a range of about 1.0 wt % to about 10.0 wt % with respect to a total weight of the amorphous indium tin oxide.

19. The electronic device of claim 18, wherein a thickness of each of the blocking layer and the skin layer is in a range of about 5 nm to about 10 nm, and
a thickness of the reflective layer is in a range of about 80 nm to about 100 nm.

20. The electronic device of claim 17, wherein the anode electrode further includes an additional blocking layer disposed between the circuit layer and the reflective layer,
the reflective layer is interposed between the blocking layer and the additional blocking layer, and
the additional blocking layer includes the amorphous indium tin oxide (ITO).
